(19) United States
(12) Patent Application Publication
(10) Pub. No.: US 2013/0082407 A1
(43) Pub. Date: Apr. 4, 2013

(54) Integrated Circuit Package And Method

(71) Applicants: Donald C. Abbott, Norton, MA (US); Margaret Rose Simmons-Matthews, Richardson, TX (US)

(72) Inventors: Donald C. Abbott, Norton, MA (US); Margaret Rose Simmons-Matthews, Richardson, TX (US)

(73) Assignee: TEXAS INSTRUMENTS INCORPORATED, Dallas, TX (US)

(21) Appl. No.: 13/252,833

(22) Filed: Oct. 4, 2011

(51) Int. Cl. H01L 23/36; H01L 21/56

(52) U.S. Cl. 257/787; 438/118; 257/E23.101; 257/E23.116; 257/E21.502

(57) ABSTRACT

A method of making integrated circuit package assemblies including encapsulating a plurality of dies in an encapsulation layer having an exterior surface and attaching a heat sink strip to the exterior surface of the encapsulation layer. An integrated circuit package assembly and an intermediate product used in making an integrated circuit package assembly are also disclosed.

### BACKGROUND

Integrated circuits, also referred to as “IC's” or “semiconductor chips” or simply “chips,” are electronic circuits made by diffusion of trace elements into the surface of thin substrates of semiconductor material. Integrated circuits were first produced in the mid 20^{th} Century. Because of their small size and relatively low production cost, integrated circuits are now used in most modern electronics. Semiconductor chips are typically mass produced in the form of a single wafer that contains a large number of identical integrated circuits. The wafer is cut (“singulated”) into a number of individual semiconductor chips referred to as “dies” or “dice.”

Dies are “packaged” to prevent damage to the dies and to facilitate attachment of the dies to circuit boards. Various packaging materials and processes have been used to package integrated circuit dies. One conventional packaging method involves mounting individual dies in a predetermined pattern on a substrate strip. The dies mounted on the substrate strip are then encapsulated in a plastic material, such as by a transfer molding process. Next, the encapsulated dies are singulated into individual integrated circuit packages by cutting the encapsulated die/substrate strip in accordance with the predetermined die mounting pattern. Typical cutting tools include saws and punches. Each integrated circuit package generally includes at least one die and the underlying portion of the substrate strip on which it was mounted. The underlying substrate strip is sometimes a lead frame to which the die is electrically connected.

Over the years, integrated circuits have become physically smaller and more complex. As a result, heat dissipation from such IC packages is a continuing design consideration.

Heat generated by integrated circuit packages may be transferred away from an encapsulated die by various techniques. One technique is to simply transfer heat from the die to the encapsulation material in which the die is encased. The encapsulation material transfers the heat to the surrounding environment by conduction and/or radiation. Plastic encapsulation material is generally not a good heat conductor or radiator and thus this technique, by itself, may not be sufficient for a die that generates a substantial amount of heat.

Another heat dissipation technique involves using electrical leads to which the die is electrically connected to transfer heat away from the die. The heat is typically conducted through the lead to a lead frame, which is in turn connected to a circuit board. Since the circuit board itself must not overheat, this technique is not always desirable.

In another technique, a he sink is mounted on the top of a die before the die is encapsulated. The heat sink receives heat from the die and transfers it away from the die. In some cases the heat sink is completely covered by encapsulating material and simply transfers heat to the encapsulating material which, in turn, transfers it to the surrounding environment. In this situation the heat transfer to the encapsulating material may be improved by the presence of the heat sink but, again, the encapsulating material is typically not a good heat conductor or radiator. In other cases the heat sink is only partially covered with encapsulation material. An exposed portion of the heat sink may then efficiently transfer heat directly to the surrounding environment. A problem with this technique is that moisture, or other contaminants, may enter the encapsulant casing through the interface between the encapsulant and the exposed surface of the heat sink and cause damage to the package.

Another technique for dissipating heat in an integrated circuit package uses an external heat sink. A thin layer of heat sink material such as copper is attached to the top surface of the IC package encapsulation layer. The heat sink layer has an identical size and shape (“footprint”) to that of the top surface of the encapsulation layer with which it is aligned. The heat sink layer receives heat from the material encapsulating the die and dissipates it more rapidly than the encapsulation layer would if no heat sink were attached. This is a frequently used technique because it overcomes various problems of the other above discussed heat dissipation techniques. According to this technique the heat sinks are small thin conductor sheets. Typically such heat sinks are formed by stamping, cutting or etching small rectangular sheets from a larger sheet of conductor material. The individual heat sinks typically are randomly oriented after manufacturing. The heat sinks are put in a bowl feed to orient them top to bottom, then are fed from the bowl feed to a preciser that orients the heat sinks in the x/y plane. Individual IC packages may be placed in a tray. A device known as a pick and place machine (for example a product sold under the name Model 830 Pick and Place System, available from Semitool) is used to handle the individual heat sinks. The pick and place machine is used to pick up each heat sink, one at a time, from the preciser and moves it past a spray head or other applicator where adhesive is applied to one surface of the heat sink. (Alternatively an adhesive can be dispensed on top of the IC encapsulation material and the heat sink placed on it, analogous to die mounting on a substrate.) The heat sink is then placed in registration with the top surface of the encapsulation layer of the IC package by the pick and place machine. Associated machine vision systems may assist in aligning and placing the heat sink on the associated encapsulation layer.

### SUMMARY

Applicants have recognized that as the size of integrated circuit packages shrink, problems may be expected using the pick and place technique described above for external heat sink mounting. As previously mentioned, the existing technique involves placing an individual heat sink in registration with the encapsulation material of an individual integrated circuit package. In slightly different words, a small sheet of heat sink material must be aligned, front to back and side to side, with the top surface of the encapsulation material. Modern IC packages now have footprints which may be less than 3 mm×3 mm. Because of the tolerances of current pick and place machines and associated vision systems, it is often very difficult to place heat sinks in exact registration with the tops of small IC packages. As a result a large amount of scrap may be produced.

Precise registration between a heat sink and the layer of encapsulation material is desirable for several reasons. 1) Maximum heat transfer to the surrounding environment is achieved when the heat sink covers the entire top surface of the encapsulation layer. 2) Misregistration between the heat sink and the encapsulant layer causes part of the heat sink to hang over the edge of the encapsulation material, which creates a larger footprint for the IC package. This is a serious problem when mounting space on circuit boards to which the IC is to be mounted is limited. 3) Any overhanging heat sink edge is esthetically unpleasing to customers. 4) An overhanging heat sink edge may come into contact with other circuit devices during installation of the IC package and such contract has the potential for peeling the heat sink off the IC package or otherwise damaging the associated IC package or adjacent circuit board components. 5) Inspection of IC package placement on a circuit board may be compromised because the board inspection vision system may look at a misaligned heat sink as opposed to the entire IC package.

Applicants have developed a method that solves the above discussed problem of mounting an external heat sink in registration with an encapsulation layer of a small IC package. According to this method a strip of heat sink material is attached to a strip of encapsulated, substrate-mounted dies prior to singulation of either strip. The two attached strips are singulated at the same time by the same cuts, in much the same manner that the multiple layers of a sandwich are sliced. The resulting integrated circuit packages each include a substrate-mounted, encapsulated die with an external heat sink layer that is mounted in registration with the top surface of the encapsulation layer. The method has the advantage that it allows “gang mounting” of heat sinks as opposed to one at a time mounting and thus considerably improves production throughput. The cost of purchasing a heat sink strip from a manufacturer is less than the cost of purchasing singulated heat sinks. Also, gang mounting eliminates the need for an expensive pick and place machine.

An integrated circuit package produced by the method described in the previous paragraph is different than an integrated circuit package produced using a pick and place machine. One difference is that the integrated circuit package produced by gang mounting of heat sinks has an adhesive layer between the heat sink layer and the encapsulant layer that has at least one cut side face.

An intermediate product of integrated circuit packages produced by such gang mounting of heat sinks is also unique. It includes a heat sink strip attached to an encapsulation layer of a substrate strip that has a plurality of encapsulated dies mounted on it. The heat sink strip is registered with the underlying substrate strip and the encapsulation layer. The encapsulated dies on the substrate strip are each adapted to become single dies of integrated circuit packages that are later singulated from the two attached strips.

### BRIEF DESCRIPTION OF THE DRAWINGS

FIG. 1 is a perspective view of one embodiment of a plurality of dies mounted on a substrate or leadframe strip.

FIG. 2 is a perspective view of the substrate and dies of FIG. 1 after encapsulation of the dies in an encapsulation layer.

FIG. 3 is an enlarged cross sectional view of a portion of the assembly of FIG. 2, showing two of the encapsulated dies, and corresponding portions of the substrate strip and encapsulation layer.

FIG. 4 is a perspective view of a heat sink strip.

FIG. 5 is the same cross sectional view as FIG. 3, except that it includes an adhesive layer on the top surface of the encapsulation layer.

FIG. 6 is a perspective view of the encapsulated, die mounted, substrate strip of FIG. 2 mounted on a pallet and showing a heat sink strip adhered to a top surface of the encapsulation layer by an adhesive layer.

FIG. 7 is an enlarged cross sectional view of a portion of the assembly of FIG. 6.

FIG. 8 is a perspective view similar to FIG. 6, showing a grid shaped cutting path for singulating this assembly into a plurality of integrated circuit packages.

FIG. 9 is a perspective view of one integrated circuit package formed by singulating the assembly shown in FIG. 8.

FIG. 10 is an enlarged cross sectional view of two integrated circuit packages formed by singulating the assembly of FIG. 8.

FIG. 11 is a cross sectional view of another embodiment of an integrated circuit package.

FIG. 12 is a flow chart of one method of making integrated circuit package assemblies.

### DETAILED DESCRIPTION

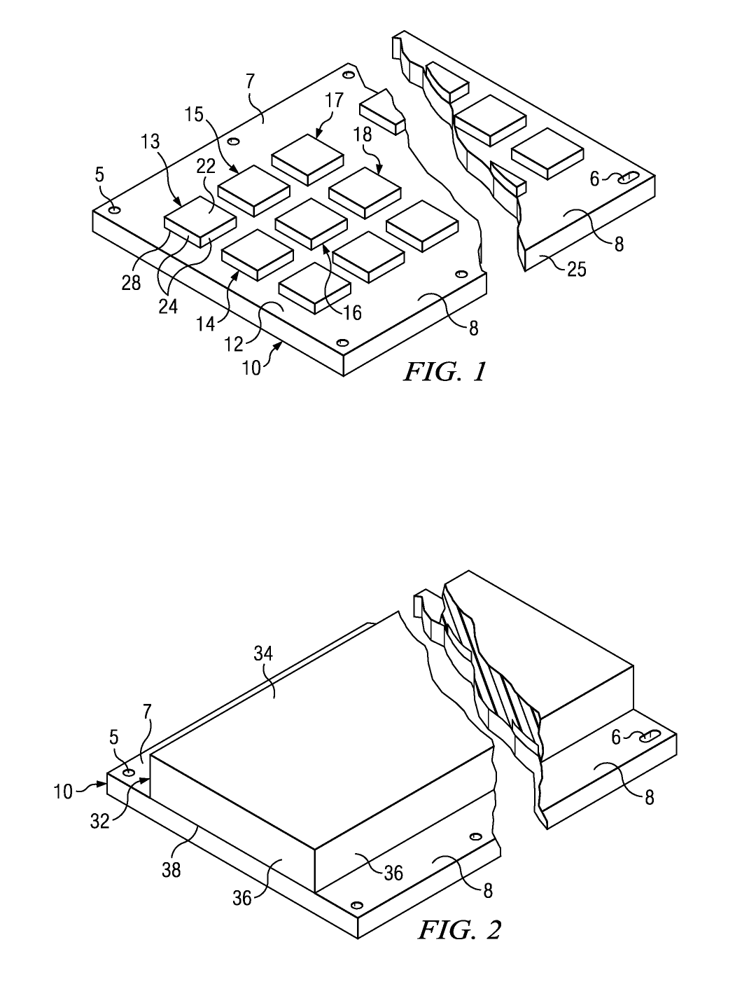

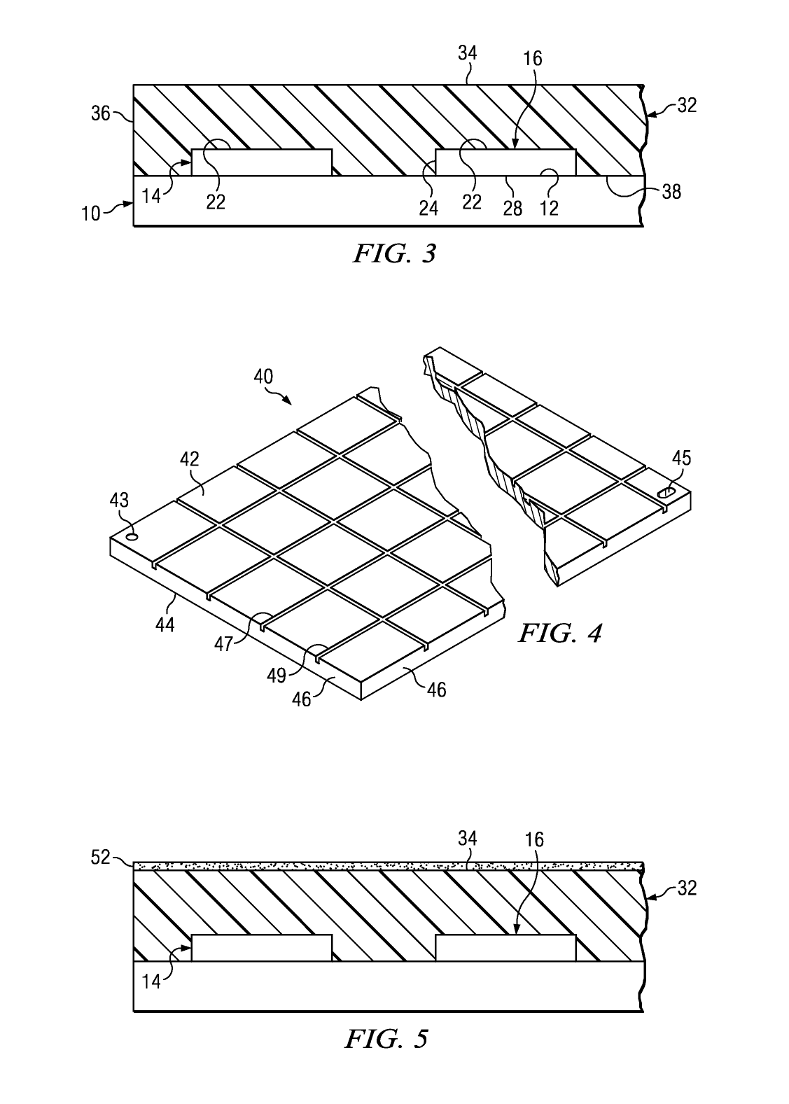

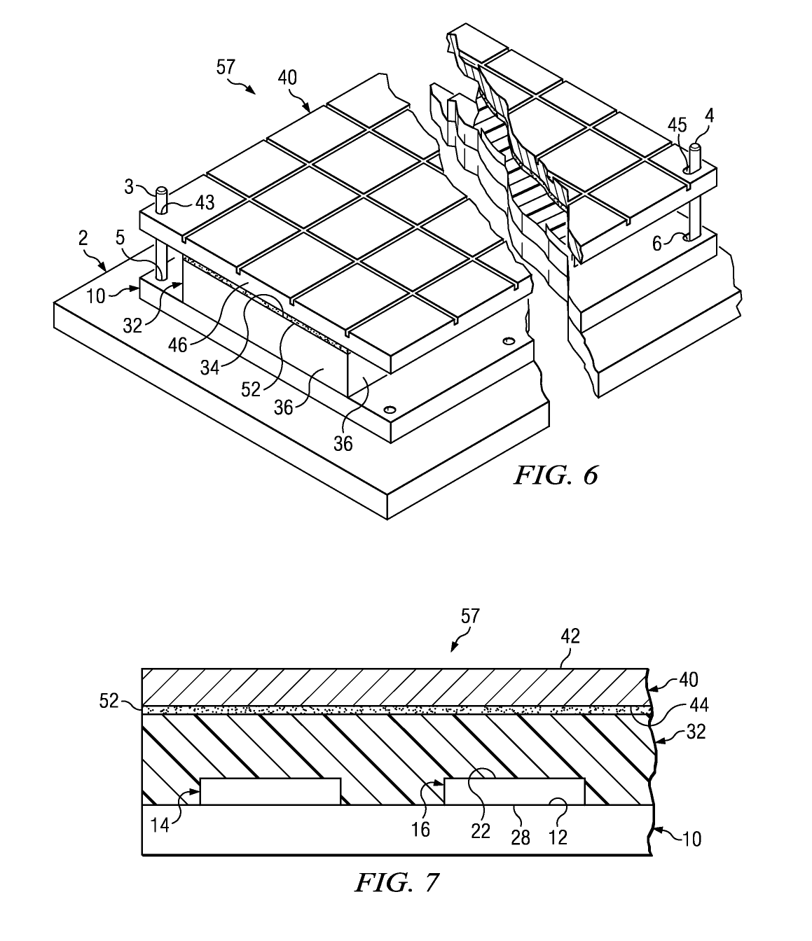

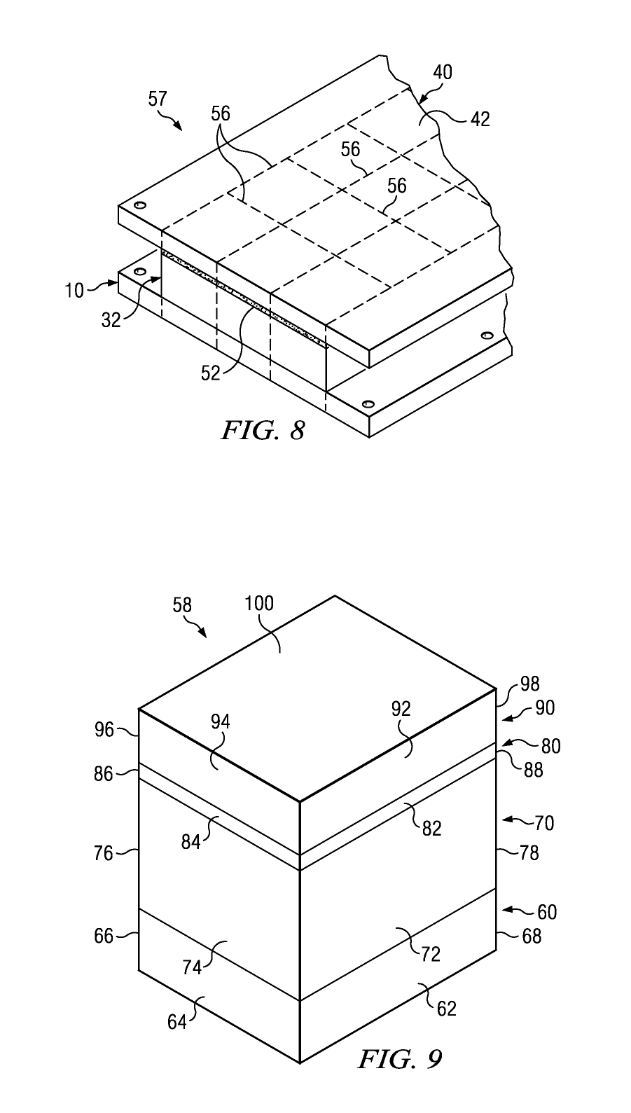

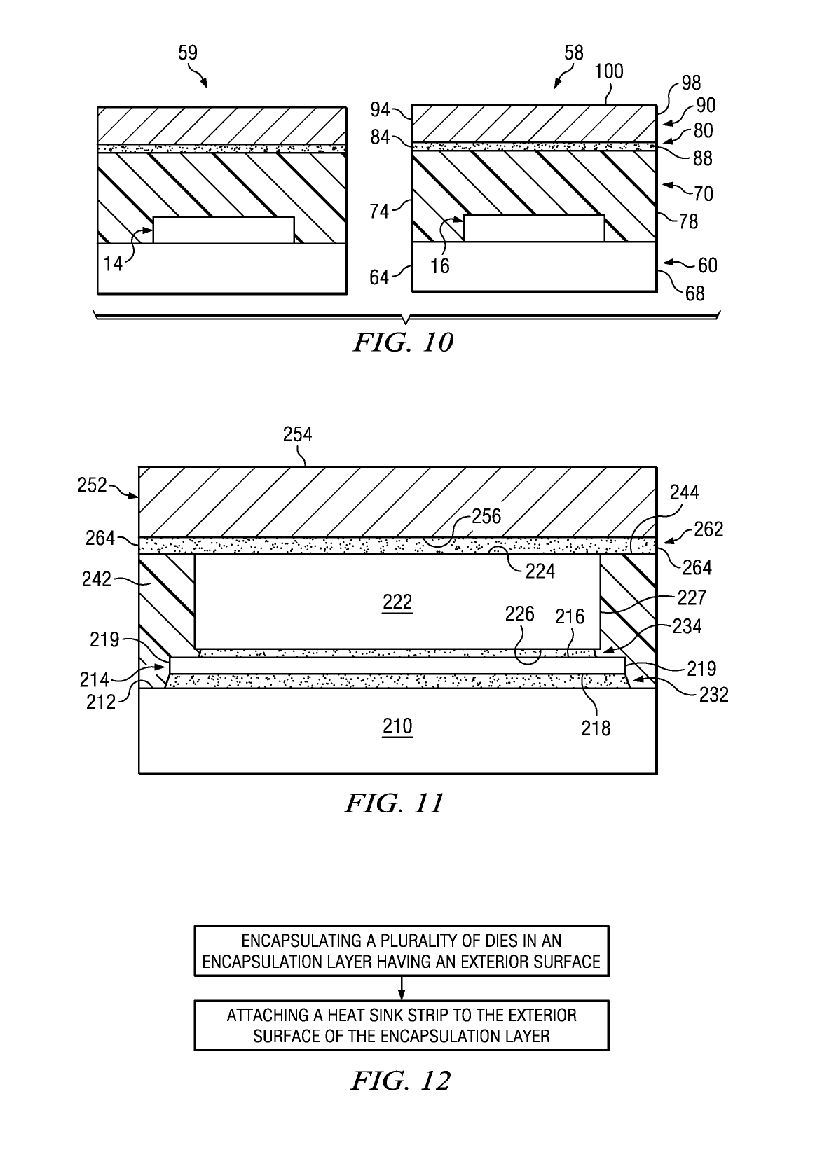

Drawing FIGS. 1-12, in general, illustrate example embodiments of a method of making a plurality of integrated circuit (“IC”) package assemblies 58, 59, FIGS. 9 and 10. A plurality of individual dies 13, 14, 15, 16, 17, 18, etc., are mounted in a predetermined die pattern, e.g. a rectangular grid, on a substrate strip 10, FIG. 1. The dies are then encapsulated within an encapsulation layer 32, FIGS. 2 and 3. A heat sink strip 40, FIG. 4, may be registered with the underlying substrate strip 10 and encapsulation layer 32 using indexing pins 3, 4 and holes 5, 6 and 43, 45, FIG. 6. The heat sink strip 40 is attached to an exterior top surface 34 of the encapsulant layer 32 by an adhesive layer 52, FIG. 5-7. The sandwiched substrate strip 10, encapsulant layer 32, heat sink strip 40 and adhesive layer 52 are then severed with a plurality of cuts extending through all of the strips and layers. The cuts are arranged in a cut pattern 56, FIG. 8, corresponding to the predetermined die pattern. The method provides integrated circuit packages 58, 59, FIGS. 9 and 10, each having a heat sink layer 90 positioned in registration with an underlying encapsulation layer 70 and an underlying substrate layer 60. Specific features and variations of this method as well as integrated circuit packages and intermediate products produced will now be described in greater detail.

FIG. 1 shows a substrate strip 10 which may be a lead frame or an organic substrate or another type of substrate. The term “substrate” as used in this specification encompasses all such variations unless otherwise expressly indicated. “Substrate strip” means a substrate layer that is adapted to be severed into a plurality of smaller substrate units during the production of IC packages. Two common substrate strip sizes are 62 mm×230 mm and 74 mm×240 mm but various other sizes may also be used. The substrate strip may have indexing holes, e.g. 5, 6, etc., located in “rails” 7, 8 of the substrate strip 10. “Rail” refers to a laterally outer portion of the substrate which does not support any dies and which is trimmed off during singulation. The width of each rail is somewhat exaggerated in the drawings for illustrative purposes. Substrates 10 are typically provided with such indexing holes during substrate fabrication, which is well known in the art. There are usually a plurality of such indexing holes provided along each rail 7, 8. In the illustrated embodiment one of the indexing holes 5 is circular and is adapted to receive an indexing pin 3, as discussed below. For example the tolerance may be about 0.002 mm. A typical pin diameter is about 1.5 mm. The second indexing hole 6 may have an elongated or slotted shape with the long axis of the hole extending parallel to a side surface 25 of the substrate. The long axis allows for limited relative movement between the substrate 10 and pallet 2 during heating that occurs during encapsulation described below. The long axis of elongated hole 6 may be, e.g., 2.0 mm longer than the diameter of an indexing pin 4. The narrow diameter may be the same as the diameter of hole 5.

Dies 13, 14, 15, 16, 17, 18, etc., shown in FIG. 1, have been “diced” from a die wafer (not shown). Each die 14 has a top surface 22, a plurality of lateral side surfaces 24 and a bottom surface 28. The dies are mounted on a top surface 12 of the substrate strip 10. (The terms “top” and “bottom” as used herein do not imply any particular orientation with respect to a gravitational field, but rather are used in a relative sense for describing the spatial relationship between various objects. The terms “up,” “down,” “upper,” “lower,” “vertical,” “horizontal” and similar terms are used in the same manner.) Dies may be of various sizes. A typical small die may have a foot print of less than about 1 mm×1 mm and a height of less than about 20 μm In one embodiment of a substrate strip used for the production of 14×14 mm IC packages, the substrate strip has a 62 mm×230 mm footprint and there are 36 dies mounted on the substrate strip. The dies are arranged in 4 symmetrically spaced “blocks.” Each block has 9 dies arranged in a 3×3 unit matrix. For simplicity of illustration the dies in FIG. 1 are shown in 3×3 blocks and the strip is shown as being only one block wide. The mounting of dies on a substrate strip in a predetermined pattern is known in the art. For example the dies may be attached to a substrate with a silver filled epoxy adhesive, such as QMI 530, or they may be attached by eutectic solder bonding or other known or later developed attachment methods. Terms such as “attached” or “mounted” or similar terms that imply a coupling or connection between objects are to be broadly construed to mean attachment that is either direct or indirect unless otherwise stated.) The dies may be placed in the predetermined pattern on the substrate strip 10 by, for example, use of a pick and place machine know in the art as a die mounter. As mentioned above, for purposes of illustration, FIG. 1 is shown as having dies 13, 14, 15, 16, 17, 18, etc. arranged in three rows on top surface 12 of substrate 10. However it is to be understood that dies may be arranged in any number of rows and columns or in a series of sub-matrices that are spaced apart on the substrate.

FIG. 2 illustrates the die mounted substrate of FIG. 1 after die encapsulated. The encapsulation of dies 14, 16, etc. mounted on a substrate through transfer molding or other encapsulation techniques is well known in the art. As is known in the art, during encapsulation, the rails 7, 8 of the substrate strip 10 are positioned outside the mold chase, and thus the rails are not encapsulated. The encapsulation layer 32 may be composed of any number of commercially available thermoset mold compounds or other encapsulation material. Layer 32 may be coextensive with substrate strip 10, excluding the rails 7, 8, and may include a relatively flat top surface 34 and a plurality of generally vertical side surfaces 36. As shown by FIGS. 2 and 3, the encapsulation layer 32 may have a bottom surface 38 that interfaces with the top surface 12 of substrate 10. The encapsulant layer 32 may also interface with top surface 22 and lateral side surfaces 24 of each die 14, 16, etc. In one nonlimiting embodiment the encapsulant layer may have a height above the top surface 22 of the substrate strip 10 of about 450 μm and the distance between the top surface 22 of each die 14, 16 and the top surface 34 of the encapsulation layer 32 may be about 100 μm.

A heat sink strip 40, such as shown in FIG. 4, may have a footprint that is the same as that of the underlying substrate strip 10. A “heat sink strip” as used herein means a sheet of conductive material that is designed to be severed into a plurality of heat sink units during the formation of IC packages. The heat sink strip 40 has generally flat top and bottom surfaces 42, 44 and lateral side surfaces 46. The heat sink strip may have a first indexing hole 43 in one corner thereof and a second indexing hole 45 in another corner thereof. The holes 43 and 45 may correspond in size, shape and position to substrate strip holes 5 and 6, respectively. In one nonlimiting embodiment the heat sink strip 40 may be a metal alloy such as copper alloy CDA 194 and may have a thickness of about 0.20 mm. The surface of the heat sink strip 40 may or may not be scored as shown in FIG. 4 and discussed in further detail below. The heat sink strip 40 is adapted to be mounted on the top surface of the encapsulation layer 32. In one embodiment, prior to mounting the heat sink strip 40 on the encapsulation layer 32, either the heat sink strip lower surface 44 or the encapsulation layer top surface 34 (or both) is coated with a thermally transmissive adhesive to provide an adhesive layer 52. FIG. 5 illustrates an adhesive layer 52 applied to the top surface 34 of the encapsulation layer 32. In one embodiment, the adhesive layer is composed of silver filled epoxy die adhesive and may have a thickness of about 50 μm. The adhesive may be applied by conventional means such as a squeegee or syringe dispenser or by any other means now known or later developed. After adhesive coating, heat sink strip 40 may be placed on the top surface of the encapsulation layer 32 by hand or by automated means. In one embodiment as shown best by FIG. 6, the substrate strip 10 may be mounted on the top surface of a pallet 2 and may be held in generally fixed relationship with the pallet 2 by two or more indexing pins 3, 4. The indexing pins are anchored in holes in the pallet 2 and are received in indexing holes 5, 6. The substrate strip 10 may be moved into position over the pallet and then lowered onto the pallet with indexing pins 3, 4 received in holes 5, 6, respectively, by conventional machine vision systems and robotics. Such vision systems and robotics are well known to those skilled in the art and will thus not be further described herein. Next, the heat sink strip 40 (after application of adhesive 52) is mounted on top of the encapsulation layer 32 of the substrate strip 10. As with the mounting of the substrate strip on the pallet 2, the heat sink strip is mounted such that indexing holes 43, 45 receive corresponding vertical indexing pins 3 and 4. This use of common indexing pins 3, 4 with corresponding indexing holes 5, 43 and 6, 45 in the substrate strip 10 and the heat sink strip 40 provides positive registration, ensuring exact alignment of the two strips 10, 40. Placing the heat sink strip 40 in proper front to back and side to side alignment (registration) with the encapsulation layer is essentially foolproof using this methodology, since the encapsulation layer 32 has already been registered with the substrate strip 40 during encapsulation. In most embodiments the adhesive must be cured at a preset temperature for some preset time (e.g. for 175° C. for 1 hour). The use of indexing pins and indexing holes ensures there is no need to adjust the position of the heat sink strip 40 after it is initially placed on the encapsulation layer 32.

FIGS. 6-8 illustrate an intermediate product 57 made in the production of integrated circuit package assemblies 58, FIG. 9. This intermediate product 57 includes dies 13-18, etc. mounted on the top surface 12 of substrate strip 10 in a predetermined die pattern. The intermediate product 57 further includes encapsulation layer 32 which encapsulates the dies 13, etc. Heat sink strip 40 overlies the substrate strip 10 and the encapsulation layer 32 and may be substantially coextensive with the substrate strip 10. The intermediate product 57 also includes adhesive layer 52 disposed between and attaching the encapsulation layer 32 to the heat sink strip 40. The intermediate product 57 may also include indexing pins 3 and 4 received in aligned holes 5, 43 and 6, 45, respectively, FIG. 6.

The intermediate product 57 is “singulated” to provide a plurality of integrated circuit packages 58, 59, FIGS. 9 and 10. “Singulation” refers to cutting the intermediate product 57 with a saw or punch in a cutting pattern, typically a rectangular grid, that corresponds to the pattern in which dies 13-18, etc. were mounted on the substrate strip 10. Each cut is made along a narrow “saw street” extending between each row and each column of dies. The cuts may extend generally perpendicular to the layers. Each singulated integrated circuit package 58, thus produced, has structure corresponding to the various layers of the intermediate product 57. FIG. 8 shows a cut pattern 56, prior to cutting in which each dashed line corresponds to a saw street. FIG. 10 shows two integrated circuit packages 58, 59 having dies 14 and 16, produced by singulation of intermediate product 57. The heat sink strip 40 prior to singulation may be, except for the indexing holes, a continuous smooth sheet. However, as shown by FIGS. 4 and 6, the heat sink layer 40 in some embodiments may be partially precut to facilitate singulation. The partial cuttings may be perforations or score lines or other partial cut lines. Score lines 47, 49, etc. may be formed with cutting tools or by photolithographic etching, for example. The score lines 47, 49, etc. correspond to cut pattern 56 shown in FIG. 8.

As best shown in FIGS. 9 and 10, each integrated circuit package 58, etc. may include a substrate layer 60 with four planar side faces 62, 64, 66, 68 and an encapsulation layer 70, which encapsulates a die, e.g. 14 (not visible in FIG. 9). The encapsulation layer has four planar side faces 72, 74, 76, 78. Each integrated circuit package 58 also has an adhesive layer 80 with four planar side faces 82, 84, 86, 88. The adhesive layer 80 attaches the encapsulation layer 70 to a heat sink layer 90 with four planar side faces 92, 94, 96, 98 and an exposed top surface 100. Corresponding side faces, e.g. 62, 72, 82, 92 of the layers 60, 70, 80, 90 are each formed by the same cut and are thus substantially coplanar. All of the planar faces of the layers, including adhesive layer faces 82, 84, 86, 88, are “cut faces,” i.e. they are formed by cutting action of a saw, punch or other cutting device. It is to be understood that “planar” as used herein means relatively planar or smooth and flat such as a surface produced by a common saw or knife cut. It does not refer to a true mathematical plane.

FIG. 11 is a cross sectional view of another IC package embodiment that may be formed using the above described methodology. In this embodiment the IC package contains multiple dies and the top surface of the top mounted die is not covered by encapsulation material. A heat sink is attached to the top surface of the upper most die and to a top surface portion of encapsulation material that surrounds the die.

As shown by FIG. 11, a substrate 210 may have a flat top surface 212. A first die 214, such a processor chip, which may have a thickness of about 50 μm, may have generally flat top and bottom surfaces 216, 218 and a plurality of lateral side surfaces 219. A second die 222, such as a memory chip, may have generally flat top and bottom surfaces 224, 226 and a plurality of lateral side surfaces 227. A first adhesive layer 232 attaches the top surface 212 of the substrate to the bottom surface 218 of the first die 212. A second adhesive layer 234 attaches the top surface 216 of the first die 212 to the bottom surface 226 of the second die. A layer 242 of encapsulation material, also sometimes referred to herein as mold compound, interfaces with the lateral sides of the first and second dies 214, 222. The top surface 244 of the encapsulation layer 242 may be generally coplanar with the top surface 224 of the second die 222. The top surface 224 of the second die 222 is not covered by encapsulation material. A heat sink 252 may have generally flat top and bottom surfaces 254, 256. Bottom surface 256 of the heat sink is attached by a layer of thermal interface adhesive 262 to top surfaces 224, 244 of the second die 222 and encapsulation layer 242, respectively. Heat from the second die 222 is thus transmitted through the thermal interface adhesive to the heat sink 252, which radiates heat to the surrounding environment. The adhesive layer 262 that extends between the encapsulation material 242 and the heat sink 252 acts as a circumscribing seal to prevent water or other contamination from reaching the dies 222, 234.

In one nonlimiting embodiment, the substrate 210 may be about 240-300 μm thick and may have a 14 mm×14 mm footprint. The first die and second die may have thicknesses of 50 μm and 280 μm, respectively. The first and second adhesive layers may have thicknesses of 40 μm and 25 μm, respectively. The thermal interface adhesive layer 262 may have a thickness of 50 μm and the heat sink 252 may have a thickness of about 200 μm. The encapsulation layer may have a thickness of about 395 μm. In another nonlimiting embodiment the two dies 214, 222 are replaced by a single die with a top surface like surface 224, which is flush with the top surface of the surrounding encapsulation layer and which is adhered to an overlying heat sink.

The IC packages illustrated in the drawings are generally representative of Ball Grid Array (BGA) type IC packages. It is to be understood that the disclosed method of making an IC package is not limited to Ball Grid Array (BGA) type IC packages and may be used to make many other types of IC packages which use external heat sinks. Such other IC packages include but are not limited to Quad Flat No leads packages (QFN's), Quad Flat Packages (QFP's), Thin Shrink Small Outline Packages (TSSOP's).

FIG. 12 illustrates one embodiment of a method of making integrated circuit package assemblies. The method includes encapsulating a plurality of dies in an encapsulation layer having an exterior surface and attaching a heat sink strip to said exterior surface of said encapsulation layer.

It will be appreciated by those skilled in the art after reading this disclosure that a new method of heat sink attachment has been described that overcomes the problem of accurate mounting of small heat sinks on small IC packages. Rather than registering heat sinks one heat sink at a time with each IC package subassembly, the heat sinks are automatically register with other IC package subassemblies en masse. This is done by mounting an unsingulated heat sink strip 40 on an unsingulated encapsulated die strip 10/32, in precise, positive registration therewith, and then singulating both strips together. This process eliminates the prior art step and associated cost of separately singulating a heat sink sheet into individual heat sinks. It also eliminates the many one at a time operations associated with applying adhesive to each separate heat sink (or each IC package subassembly) and then mounting each heat sink in registration with each associated IC package subassembly. This process may substantially improve the accuracy of heat sink registration on small IC packages, thereby reducing scrap. This process may also significantly increase production rates while obviating the need for expensive pick and place machines.

Although embodiments of certain methods and devices are expressly described herein, it will be obvious to those skilled in the art after reading this disclosure that the methods and devices disclosed herein may be otherwise embodied. The claims attached hereto are to be construed broadly to cover such alternative embodiments, except as limited by the prior art.

What is claimed is:

1. A method of making integrated circuit package assemblies comprising:
encapsulating a plurality of dies in an encapsulation layer having an exterior surface and
attaching a heat sink strip to said exterior surface of said encapsulation layer.

2. The method of claim 1 comprising, prior to said encapsulating, mounting said plurality of dies on a substrate strip in a predetermined die pattern.

3. The method of claim 3 comprising positively registering said heat sink strip with said substrate strip.

4. The method of claim 3 wherein said positively registering comprises , aligning indexing holes in said substrate strip with corresponding indexing holes in said heat sink strip.

5. The method of claim 4 wherein said aligning indexing holes comprises inserting an indexing pin through at least one pair of said corresponding indexing holes in said substrate strip and said heat sink strip.

6. The method of claim 1 comprising severing said encapsulation layer and said heat sink strip with a plurality of cuts extending through said encapsulation layer and said heat sink strip.

7. The method of claim 2 wherein said attaching said heat sink strip comprises attaching said heat sink strip to said exterior surface of said encapsulation layer with an adhesive layer.

8. The method of claim 7, comprising severing said substrate strip, said encapsulation layer, said adhesive layer and said heat sink strip with a plurality of cuts arranged in a cut pattern corresponding to said predetermined die pattern.

9. The method of claim 8 comprising, prior to said severing, forming a plurality of partial cuts in said heat sink strip corresponding to said predetermined die pattern.

10. The method of claim 1 wherein said encapsulating a plurality of dies comprises completely covering said dies with encapsulation material.

11. The method of claim 1 wherein said encapsulating a plurality of dies comprises covering lateral side portions of said dies with encapsulation material while exposing top surface portions of said dies and further comprising attaching said heat sink strip to said exposed top surface portions of said dies.

12. An intermediate product for use in the production of a plurality of integrated circuit package assemblies comprising:
a substrate strip;
a plurality of dies attached to said substrate strip, said dies being arranged in a predetermined die pattern on said substrate strip;
an encapsulation layer encapsulating said plurality of dies;
a heat sink strip overlying said substrate strip and said encapsulation layer and being substantially coextensive with said substrate strip; and
an adhesive layer disposed between and attaching said encapsulation layer and said heat sink strip.

13. The intermediate product of claim 12 wherein:
said substrate strip comprises a first hole therein;
said heat sink strip comprises a first hole therein; and
a first indexing pin is received in said first hole in said substrate strip and said first hole in said heat sink strip.

14. The intermediate product of claim 12 wherein:
said substrate strip comprises a second hole therein;
said heat sink strip comprises a second hole therein; and
a second indexing pin is received in said second hole in said substrate strip and said second hole in said heat sink strip.

15. The intermediate product of claim 12 wherein said encapsulation layer has a height at least equal to the height of said dies.

16. The intermediate product of claim 12 wherein said heat sink layer has precuts therein corresponding to said predetermined die pattern.

17. An integrated circuit package assembly comprising:
at least one die;
an encapsulation layer encapsulating said at least one die;
a heat sink layer overlying said encapsulation layer; and
an adhesive layer disposed between said encapsulation layer and said heat sink layer, wherein said adhesive layer comprises at least one of cut edge face.

18. The integrated circuit package assembly of claim 17, wherein said at least one die comprises a top surface portion and wherein said encapsulation layer covers said top surface portion of said at least one die.

19. The integrated circuit package assembly of claim 17, wherein said at least one die comprises a top surface portion and wherein said encapsulation layer does not cover said top surface portion of said at least one die.

20. The integrated circuit package assembly of claim 17, wherein said heat sink layer, said adhesive layer and said encapsulation layer each comprise a cut side face which is coplanar with the side faces of the other layers, on a least one side of said integrated circuit package.
